(19) United States
(12) Patent Application Publication
(10) Pub. No.: US 2016/0261179 A1
(43) Pub. Date: Sep. 8, 2016

(54) METHODS AND APPARATUS INCLUDING INTEGRATED CONDUCTING AND INDUCTIVE ELEMENT FOR PROVIDING CURRENT

(71) Applicant: ATI Technologies ULC, Markham (CA)

(72) Inventors: Philippe Blanchard, Markham (CA); Alan Wu, Toronto (CA)

(73) Assignee: ATI Technologies ULC, Markham (CA)

(21) Appl. No.: 14/635,541

(22) Filed: Mar. 2, 2015

(51) Int. Cl. H02M 1/088; H01F 27/28; H05K 1/02; H05K 1/16; H05K 3/30; H05K 1/18

(52) U.S. Cl. CPC H02M 1/088; H05K 3/30; H05K 1/181; H05K 1/0296; H05K 1/165; H01F 27/2804; H05K 2201/10272

(57) ABSTRACT

Apparatus include(s) a package having a load, and methods of making an electronic circuit include disposing the package on a printed circuit board. The apparatus include(s) an integrated conducting element and inductive element disposed on the printed circuit board and connected to the package that includes the load. The methods include disposing the integrated conducting element and inductive element on the printed circuit board so that the integrated conducting element and inductive element connects to the package. The integrated conducting element and inductive element includes a conducting element integral with an inductive element. The inductive element includes a magnetic element and a winding element. The winding element comprises a portion of the conducting element.

### BACKGROUND OF THE DISCLOSURE

The disclosure relates generally to electronic circuit assemblies and more particularly to methods and apparatus that affect a current delivery path to a processor.

Processors for which high current is needed or desired, such as numeric processors such as central processing units (CPUs) and graphics processing units (GPUs), typically receive current routed through a power plane or planes within a printed circuit board. Such power planes, which are commonly copper plane layers, have associated losses and printed circuit board size requirements. The losses result in increased generation of heat, which in turn increases the cost and/or size of the thermal solution needed to maintain a particular level of performance.

While improved power delivery to a high current load such as a CPU or GPU could be realized, to some degree, by increasing the number of power planes or by placing the power source unit closer to the high current load, the losses due to the printed circuit board will still be significant.

### BRIEF DESCRIPTION OF THE DRAWINGS

The embodiments will be more readily understood in view of the following description when accompanied by the below figures and wherein like reference numerals represent like elements, wherein:

FIG. 1 is a functional block diagram illustrating an example electronic device including a power converter and an integrated circuit such as a processor, where the power converter includes a power filter with an integrated conducting element and inductive element that may be disposed on and/or above a printed circuit board and connected to the integrated circuit;

FIG. 2 illustrates a layout of an example electronic circuit assembly that may be implemented within the example electronic device of FIG. 1;

FIG. 3 illustrates another example electronic circuit assembly;

FIG. 4 illustrates yet another example electronic circuit assembly;

FIG. 5 illustrates another example electronic circuit assembly;

FIG. 6 is a flowchart of an example method of making an electronic circuit that may include an integrated conducting element and inductive element that may be disposed on and/or above a printed circuit board and connected to a load;

FIG. 7 is a schematic diagram showing an example of greater detail of switching elements and a power filter of an n-phase power converter;

FIG. 8 illustrates an example of a conducting element having sense points integral with the conducting element;

FIG. 9 illustrates yet another example electronic circuit assembly;

FIG. 10 is an example schematic diagram of inductive components for use in a two-stage, n-phase power converter;

FIGS. 11 and 12 are a side view and a top view, respectively, of an example integrated conducting element and magnetic elements, and other components, that may be used to implement one phase of a two-stage, n-phase power converter; and

FIG. 13 is a block diagram illustrating one example of an electronic circuit forming system.

### DETAILED DESCRIPTION OF THE PREFERRED EMBODIMENTS

Briefly, methods and apparatus for increasing current delivery to a high current load such as a CPU or GPU, and increasing efficiency thereof, are disclosed. The methods and apparatus may be implemented to increase current delivery and efficiency within an electronic device (e.g., a mobile or smart phone, a phablet, a tablet, a laptop computer, portable media player, or any other suitable device including, for example, a processor to which a high supply of current is needed or desired). In one embodiment, apparatus may include(s) a package having a load (e.g., a package having an ASIC, a package having a processor such as a CPU or GPU, etc.), and methods of making an electronic circuit may include disposing a package having a load on a printed circuit board (e.g., on a top surface of the printed circuit board). The apparatus may include(s) an integrated conducting element (e.g., busbar) and inductive element disposed on and/or above the printed circuit board and connected to the package that includes the load. The methods may include disposing an integrated conducting element and inductive element on the printed circuit board so that the integrated conducting element and inductive element connects to the package. The integrated conducting element and inductive element may include a conducting element integral with an inductive element, where the inductive element may include a magnetic element and a winding element. The winding element may be comprised of a portion of the conducting element.

In one example, the integrated conducting element and inductive element may be coupled to switching elements of a power converter, such as a buck converter, so that the power converter is configured to control a current provided to the load (e.g., CPU or GPU) by the integrated conducting element and inductive element without providing the current to the load through a plane within the printed circuit board.

In another example, a second inductive element may also be integral with the conducting element. For example, the second inductive element may include a second magnetic element and a second winding element, and the first and second winding elements may each be comprised of a portion of the conducting element. That is, the first and second winding elements may be integral with the conducting element to form a monolithic single integrated assembly. This single assembly may connect multiple switching transistor phases of a power converter to the load, and may provide the necessary inductive components of the power filter of the power converter, without using, for example, copper planes within the printed circuit board to deliver current to the load.

In yet another example, the power converter may include serially connected inductive elements that are both/all integral with the conducting element so as to implement a multi-stage power filter with improved voltage ripple attenuation characteristics.

In another example, the integrated conducting element and inductive element (including one or more magnetic elements and winding elements, as discussed above) may be connected to the package in a first plane (e.g., at the package level of the load (ASIC, GPU, CPU, etc.)) and mounted to the printed circuit board in a second plane (e.g., at the level of the board surface). Solder paste, for example, may compensate for misalignment between the integrated conducting element and inductive element and the package in the first plane and for misalignment between the integrated conducting element and inductive element and the printed circuit board in the second plane. The solder paste may be used to accommodate the tolerances inherent in the manufacturing of the integrated conducting element (e.g., busbar) and inductive element. During a re-flow process, melting of the solder paste may bond the integrated conducting element and inductive element to the load as well as to the printed circuit board at two different levels.

In a further example, the package may include an outer side that has a stiffener “ring” or frame thereon with a conducting element around a border (e.g., perimeter) of the outer side. If desired, the package stiffener ring may be integral with the conducting element of the integrated conducting element and inductive element. That is, the conducting element around the border of the outer side of the package may be integral with the conducting element of the integrated conducting element and inductive element.

Among other advantages, for example, the disclosed methods and apparatus avoid the need to use a power plane or planes within the printed circuit board to deliver current to the load (e.g., CPU or GPU). As such, losses including the generation of excess heat may be minimized and, in some cases, the printed circuit board may be smaller and better layout may be achieved. For example, as described below, various configurations of the conducting element (e.g., a busbar) may be used outside of (e.g., disposed on and/or above a surface of) the printed circuit board in order to accommodate other structures that are also present on the printed circuit board. There is no need to use an inner layer(s) of the printed circuit board to connect an inductor used in the power converter (e.g., a buck converter) to a power delivery plane. Moreover, by integrating the conducting element (e.g., busbar) with the inductive element(s) of a power converter (e.g., buck converter) and connecting the integrated conducting element and inductive element(s) to the package that includes the load, without the conducting element spanning inside of the printed circuit board, performance and effectiveness in power delivery is maximized and the requirements for an adequate thermal solution are correspondingly reduced. Other advantages will be recognized by one of ordinary skill in the art.

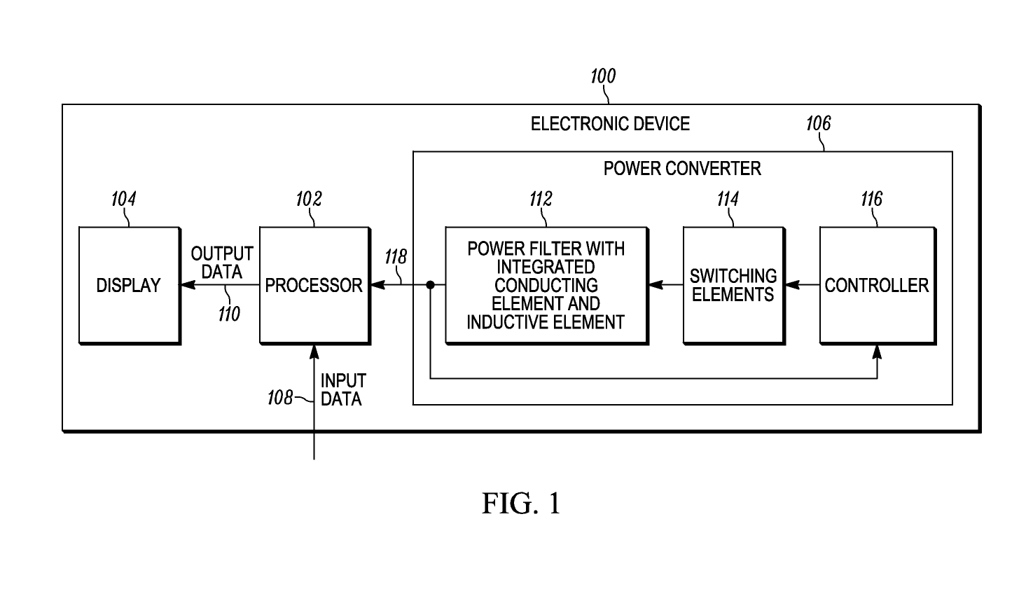

FIG. 1 is a functional block diagram illustrating an example electronic device 100 including a processor 102 as an example load, a display 104, and a power converter 106 (e.g., a buck converter). The electronic device 100 may be any suitable electronic device such as, but not limited to, a mobile or smart phone, a phablet, a tablet, a laptop computer, portable media player, or any other suitable device in which current supply to a processor(s) of the device is needed or desired, such as but not limited to a device with a processor(s) that draws a relatively high current. An example of such a processor(s) may include, in some cases, a graphics processing unit (GPU), a central processing unit (CPU), and/or an accelerated processing unit (APU), which as known in the art includes one or more CPU cores and one or more GPU cores on the same die. Such an APU may be, for example, an APU as sold by Advanced Micro Devices, Inc. (AMD) of Sunnyvale, Calif. Additionally or alternatively, the processor(s) may perform general-purpose computing on GPU, may include one or more digital signal processors (DSPs), one or more application-specific integrated circuits (ASICs), and/or any suitable processor(s). It will be understood from the disclosure herein that the electronic device 100 may include other components such as, for example, one or more memories, one or more input, output, or input/output devices in addition to or instead of the display 106, one or more peripheral devices, etc., which are not shown in FIG. 1 for ease of illustration and explanation.

The processor 102 may receive input data 108 and provide output data 110, e.g., for display on the display 104. It will be appreciated that the output data 110 may be provided to the display 104 through one or more suitable additional components, such as an interface circuit, a bus, etc. Additionally, as further described below, the power converter 106 may include a power filter 112 with an integrated conducting element and inductive element (e.g., including a magnetic element and a winding element, as further described below), switching elements 114, and a controller 116. An output signal 118 from the power filter 112 may be provided to the processor 102 and may also be fed back to the controller 116 as further shown in FIG. 1. By implementing the power filter 112 with an integrated conducting element and inductive element as further described below, the power filter 112 may allow necessary or desired high current delivery from the controller 116, which may be or may include a DC-to-DC converter, to the processor 102 without the need to utilize a power delivery plane within a printed circuit board for current delivery. As a result, current delivery may be more efficient, and better layout on the printed circuit board may be achieved in the absence of the need to utilize a power delivery plane within the printed circuit board.

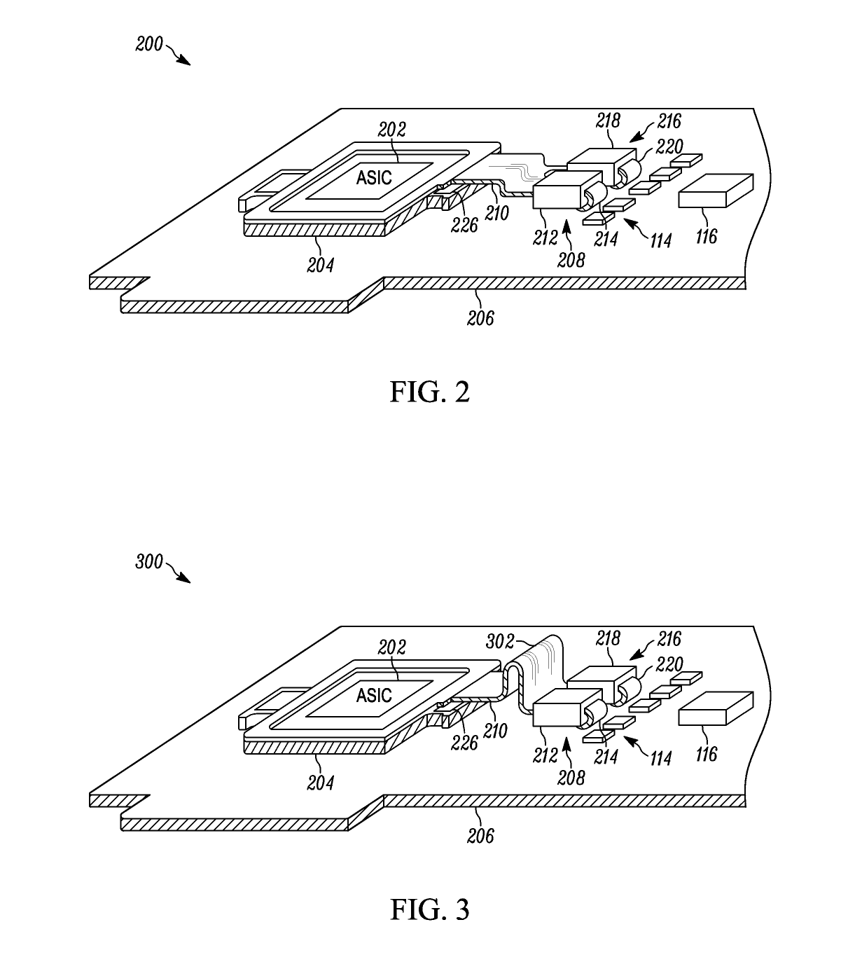

FIG. 2 illustrates a layout of an example electronic circuit assembly 200 that may be implemented within, for example, the example electronic device 100. As shown in FIG. 2, the processor 102 may be, by way of example, an ASIC 202 within a package 204 disposed on and/or above a printed circuit board 206 (e.g., on and/or above a surface of the printed circuit board 206). The example electronic circuit assembly 200 may further include the switching elements 114 and the controller 116 of the power converter 106 disposed on the printed circuit board 206. The switching elements 114 may be, for example, MOSFETs or any other suitable switching elements for use in, for example, a buck converter when the power converter 106 is implemented as a buck converter. In other examples, the power converter 106 may be a boost converter, a flyback converter, or any other suitable converter depending upon the application(s) for which the power converter 106 is used. As shown in FIG. 2 and further described below, losses that would previously have been associated with using, for example, power delivery planes within the printed circuit board 206 are minimized by the use of an integrated conducting element and inductive element disposed on and/or above a surface (e.g., a top surface) of the printed circuit board 206.

For example, as shown in FIG. 2, an integrated conducting element and inductive element 208 may include a conducting element 210, such as a busbar, that is integral with a magnetic element, such as a magnetic core 212. The integrated conducting element and inductive element 208 may further include a winding element 214, where the winding element 214 and the magnetic element or core 212 may form the inductive element that is integral with the conducting element 210. Thus, in the example shown in FIG. 2, the winding element 214 may be integral with the conducting element (e.g., busbar) 210. As such, it will be understood that the winding element 214, and any winding element discussed herein, need not be or include any actual winding, but may be or include a conducting element (e.g., the conducting element 210) that achieves the same or similar effects as a winding (e.g., that similarly presents an inductance in conjunction with the magnetic element (e.g., 212)). It will further be understood that the integrated conducting element and inductive element 208 may, therefore, be described as, for example, an integrated conducting element 210 and magnetic core 212.

As further discussed below, in some embodiments, the magnetic core 212 may be made of ferrite and may thus be a non-conductive ceramic ferromagnetic material. In other embodiments, the magnetic core 212 may be formed from powdered iron. The conducting element 210 of the integrated conducting element and inductive element 208 may be connected to the package 204 that includes the ASIC 202 (or other load) therein. The conducting element 210 may be connected to the package 204 above or on a surface of the printed circuit board 206 so that the power filter 112 of the power converter 106 is advantageously not connected to the package 204 by a power delivery plane within the printed circuit board 206. For example, the conducting element 210 may be disposed on and/or above a surface of the printed circuit board 206 as discussed above and may also be directly connected to the package 204 (e.g., by solder paste or by being integrally formed with a frame of the package, as discussed below) so as to maximize current delivery and the efficiency thereof to the ASIC 202.

As further shown in FIG. 2, in some embodiments, a multiple-phase implementation of the power converter 106 may be realized and the conducting element 210 may be expanded to accommodate any number of phases to suit the application and current needs of the ASIC 202 (or other load). In FIG. 2, a two-phase implementation is shown in which the electronic circuit assembly 200 may include a second inductive element 216. The second inductive element 216 may also be integral with the conducting element 210. It will be appreciated from the disclosure herein that more than two phases may be used, if desired, and that multiple phases may also be implemented with multiple conducting elements, if desired. The use of multiple phases as shown may be advantageous in that such an implementation allows merging of current from multiple paths in the conducting element 210, along with the aforementioned benefits of the conducting element 210 being disposed on and/or above the printed circuit board 206 instead of an implementation that uses power delivery planes within the printed circuit board 206 to deliver current to the ASIC 202. Additionally, the merging of current from multiple phases may have a desirable current ripple cancelling effect due to interleaved phases. As shown in FIG. 2, the second inductive element 216 may include a second magnetic element or core 218 and a second winding element 220. As with the (first) winding element 214, the second winding element 220 may in some examples be integral with the conducting element (e.g., busbar) 210.

In one example, the (first) magnetic core 212 and the second magnetic core 218 each include a component formed from powdered iron, and the first magnetic core 212, the second magnetic core 218, and the conducting element 210 are formed into the aforementioned integral structure by, for example, pressing the first and second magnetic cores 212 and 218 around or onto a frame of the conducting element 210 (e.g., busbar) at substantially the same time. By pressing the first and second magnetic cores 212 and 218 around or onto a frame of the conducting element 210 at substantially the same time, closer alignment between the first and second magnetic cores 212 and 218, and closer alignment between the conducting element 210 and the first and second magnetic cores 212 and 218, may be achieved. In this manner, the manufacturing of the completed integrated assembly of the magnetic cores 212 and 218 and the conducting element 210 may be more easily performed. Multiple stage power filters, which are further discussed below and which may or may not also be implemented with multiple phases, may also be formed into an integral structure by pressing multiple magnetic cores around or onto a frame or frames of the conducting element 210 and/or other conducting element(s) at essentially the same time. Returning to the two-phase example discussed above, the completed integrated assembly of the magnetic cores 212 and 218 and the conducting element 210 may then be soldered onto the printed circuit board 206 as further discussed herein.

In another example, the (first) magnetic core 212 and/or, if present, the second magnetic core 218 and/or any additional magnetic cores used to implement additional phases (not shown in FIG. 2), may be made of ferrite. For example, either or both of the first and second magnetic cores 212 and 218 may be of ferrite material. Either or both of the first and second magnetic cores 212 and 218 may, for example, each be made of two halves that are glued together around the conducting element 210 during manufacturing.

It is further noted that the conducting element 210 may be connected (e.g., soldered) to the package 204 by any suitable path from the controller 116, the switching elements 114, and the first and, if applicable, second magnetic cores 212 and 218. For example, the conducting element 210 may be shaped so as to pass over other structures, such as memory devices, etc., on the printed circuit board 206, and/or may have various non-horizontal sections (e.g., vertical or other suitable non-horizontal sections) to accommodate, among other considerations, the layout of structures on the printed circuit board 206. The physical shape of the integrated magnetic core(s) 212 (and if applicable, 218) and conducting element 210 is not limited to what is shown in the drawings.

In FIG. 2, a surface mount version of the integrated magnetic cores 212 and 218 and conducting element (e.g., busbar) 210 is shown. The conducting element 210 and the magnetic cores 212 and 218 may be soldered onto the printed circuit board 206 using standard solder pads and manufacturing processes. The solder pads or footprint at the printed circuit board 206 may be that of a standard inductor. The footprint at the landing of the package 204 may be custom-shaped. Thus, one or more solder pads 226 may be included on the package 204 and may be customized to, for example, the dimensions and/or geometry of the package and conducting element 210 for soldering the conducting element 210 to the package 204.

In the implementation as illustrated in FIG. 2, the integrated conducting element 210 and first and second magnetic cores 212 and 218 used in a multiple-phase implementation connect to the package 204 in a first plane; for example, the conducting element 210 may connect to the package 204 in a plane in which the one or more solder pads 226 are disposed. Additionally, the integrated conducting element 210 and first and second magnetic cores 212 and 218 are mounted to the printed circuit board 206 by connecting to the printed circuit board 206 in a second plane. Suitable solder pads or footprint may be etched on the printed circuit board 206 and the conducting element 210 may be soldered to such solder pads or footprint. A suitable layout symbol may be created for each version of the integrated conducting element 210 and magnetic core(s) 212 (and 218, if applicable), e.g., from a single-phase version through a highest number of phases that may be used in various implementations.

In practice, there will be tolerance in the height of the first plane (e.g., at the level of the package 204) and the second plane (e.g., at the level of the printed circuit board 206). The use of a filler material such as solder paste may compensate for misalignment between (i) the integrated conducting element 210 and magnetic core(s) 212 and 218 and (ii) the package 204 in the first plane, and may compensate for misalignment between (i) the integrated conducting element 210 and magnetic core(s) 212 and 218 and the printed circuit board 206 in the second plane. Proper design of the layout symbols may also compensate for manufacturing variability of the integrated conducting element 210 and magnetic core(s) 212 (and if applicable, 218).

FIG. 3 illustrates another example electronic circuit assembly 300. The electronic circuit assembly 300 is similar to the electronic circuit assembly 200 of FIG. 2 except that in FIG. 3, the electronic circuit assembly 300 is shown with the conducting element 210 including a fold 302. In general, in the various examples described herein, the conducting element 210 may if desired include at least one fold, such as the fold 302, so as to provide increased inductance of the integrated conducting element 210 and magnetic core(s) 212 (and if applicable, 218) relative to an inductance that the integrated conducting element 210 and magnetic core(s) 212 (and if applicable, 218) would have had without the at least one fold.

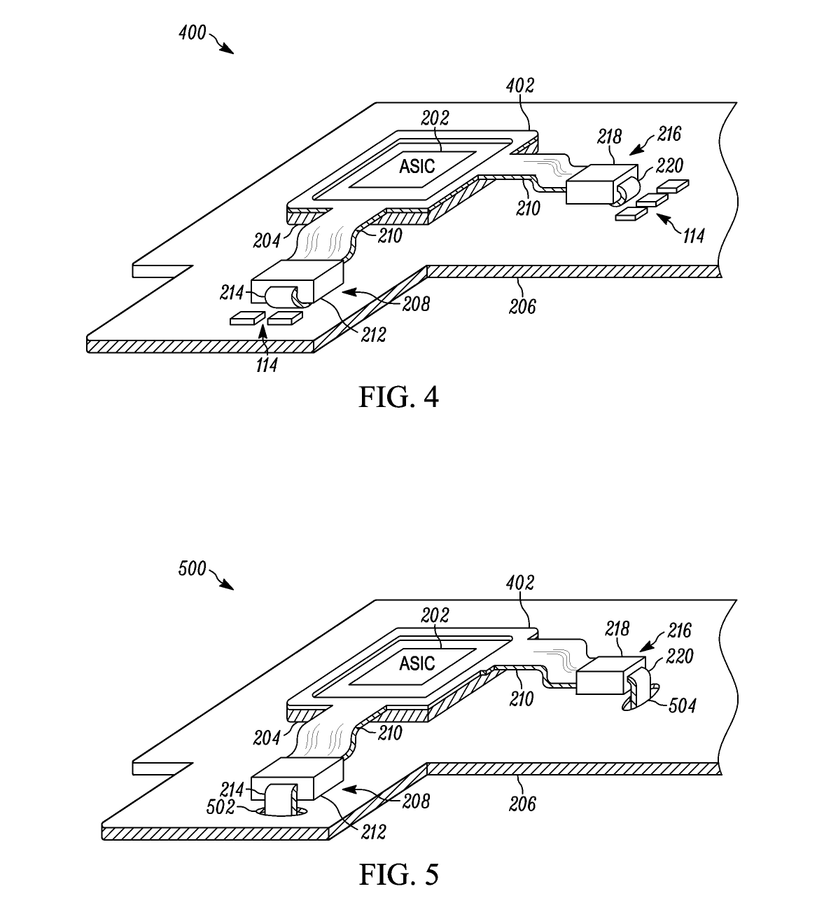

FIG. 4 illustrates yet another example electronic circuit assembly 400 in which the integrated conducting element 210 and magnetic cores 212 and 218 used to implement a multi-phase power converter 106 are formed with the package 204 as a single co-planar entity. FIG. 4 demonstrates, among other things, that the multi-phase conducting element 210 and magnetic cores (e.g., 212 and 218) may be implemented in different ways and connect to the ASIC 202 (or other load) at different locations. In particular, the package 204 may have an outer (e.g., upper) side and the outer side of the package 204 may have a conducting element or “frame” 402 extending partially or completely around a border (e.g., perimeter, circumference, etc.) thereof. The conducting element or frame 402 around, for example, the perimeter of the outer side of the package 204 may be integrally formed with the conducting element 210. As such, it will be appreciated from the present disclosure that in FIG. 4, the first and second magnetic cores 212 and 218 and the first and second winding elements 214 and 220 are still integral with the conducting element 210 and may still form a multi-phase integrated conducting element and magnetic cores as is the case in FIG. 2. The integrated conducting element 210 and frame 402 may be made of or may include, for example, copper, an alloy including copper, nickel-plated copper, aluminum, or any suitable composition.

In the example of FIG. 4, the need to use soldering to compensate for misalignment in one of the two planes mentioned above with respect to FIG. 2 is advantageously removed, at least in most situations where copper is a significant element of the integrated conducting element 210 and frame 402, as opposed to, for example, aluminum. That is, each of the package 204 and the multi-phase conducting element and magnetic cores are mounted on the printed circuit board 206 in a first plane, and are electrically connected thereto by, for example, suitable soldering. In the example of FIG. 4, unlike in the example of FIG. 2, solder paste is not needed to compensate for misalignment in a second plane.

FIG. 5 illustrates another example electronic circuit assembly 500 in which the multi-phase integrated conducting element 210 and magnetic cores 212 and 218 are formed with the package 204 as a single co-planar entity, as in FIG. 4, and in which the multi-phase conducting element 210 and magnetic cores 212 and 218 are connected to an underside of the printed circuit board 206 using at least one through hole—in the illustrated example, using through holes 502 and 504. If desired, in the particular implementation shown in FIG. 5, one of the through holes 502 and 504 may be used, while the other of the through holes 502 and 504 may be omitted and surface mount techniques such as those discussed above may be used. The use of through holes such as the through holes 502 and 504 removes the constraint of the integrated conducting element (e.g., busbar) 210 and magnetic cores 212 and 218 being flush with the printed circuit board 206, thus easing manufacturability and allowing additional variability (e.g., in placement of other components such as but not limited to memory) during assembly of the printed circuit board 206.

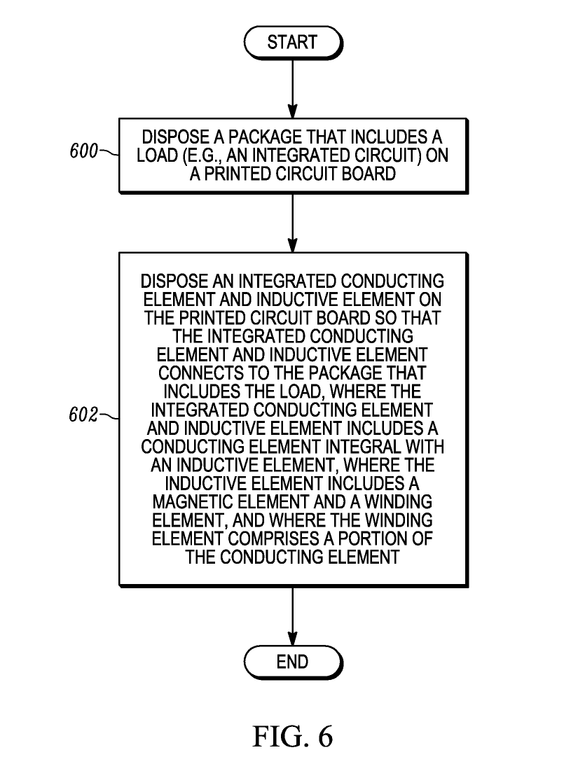

FIG. 6 is a flowchart of an example method of making an electronic circuit. The method illustrated in FIG. 6 may be performed in accordance with one or more suitable circuit construction and assembly techniques, including surface mounting, soldering, pressing (e.g., pressing the first and second magnetic cores 212 and 218 around or onto a frame of the conducting element 210 as described above), etc. Although the method is described with reference to the illustrated flowchart in FIG. 6, it will be appreciated that many other ways of performing the acts associated with the method may be used. For example, the order of some operations may be changed, and some of the operations described may be optional. Additionally, while the method may be described with reference to the electronic device 100 and electronic circuit assemblies including the electronic circuit assemblies 200, 300, 400, and 500, it will be appreciated that the method may be implemented with respect to other devices and assemblies as well.

As shown in block 600, the method includes disposing a package that includes a load (e.g., an integrated circuit) on a printed circuit board, such as disposing the package 204 that includes the ASIC 202 on the printed circuit board 206.

As shown in block 602, the method includes disposing an integrated conducting element and inductive element on the printed circuit board so that the integrated conducting element and inductive element connects to the package that includes the load (e.g., integrated circuit such as an ASIC), where the integrated conducting element and inductive element includes, for example, a conducting element (e.g., the conducting element 210, such as a busbar) integral with an inductive element, the inductive element including a magnetic element (e.g., magnetic core such as the magnetic core 212) and a winding element (e.g., 214), where the winding element (e.g., 214) comprises a portion of the conducting element 210.

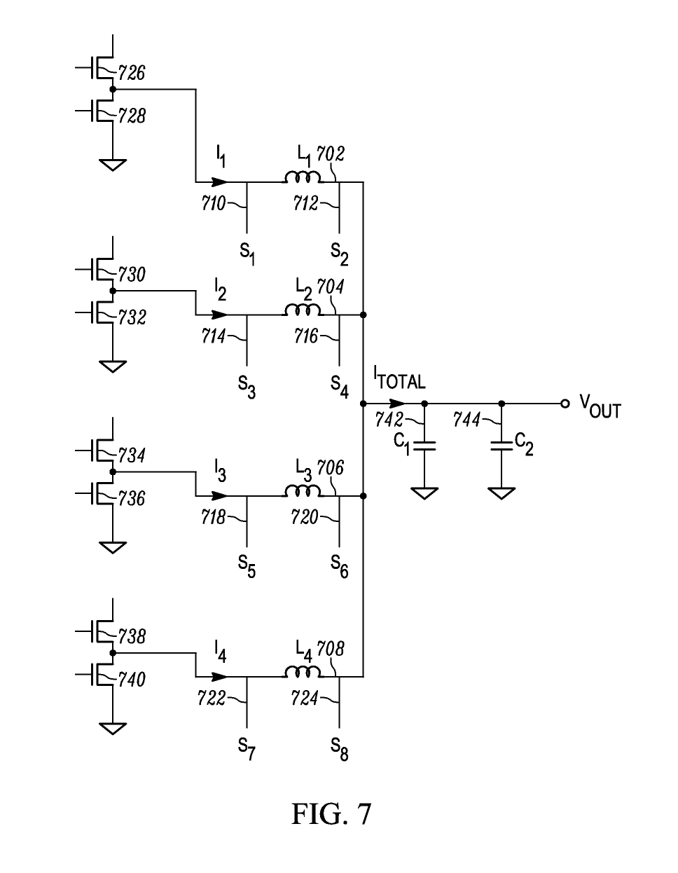

FIG. 7 is a schematic diagram showing an example of greater detail of the switching elements 114 and the power filter 112 of an example n-phase power converter, which may be used in an implementation of the power converter 106. The illustrated example may be used in an implementation of an n-phase integrated conducting element and inductive element by making each of the illustrated inductive components 702, 704, 706, and 708, which are further discussed below, integral with an n-phase conducting element such as the conducting element 210. Any suitable number of phases n may be implemented, including less than the four phases that are illustrated in FIG. 7. Each inductive component 702-708 may include a magnetic core that surrounds a portion of the conducting element 210, which, with reference to the discussion of FIG. 2 above, may be integral with a winding element of each inductive component. For example, each magnetic core may be a box-like component surrounding a portion of the conducting element 210 as shown in FIG. 2.

Further inductive components beyond the inductive components 702, 704, 706, and 708 may be implemented for any additional ones of the n phases not illustrated. The inductive components 702, 704, 706, and 708 may have inductances of L₁, L₂, L₃, and L₄. The n-phase power filter 112 may also include sense points 710 and 712 corresponding to the first inductive component 702 (e.g., corresponding to a first phase), sense points 714 and 716 corresponding to the second inductive component 704 (e.g., corresponding to a second phase), sense points 718 and 720 corresponding to the third inductive component 706 (e.g., corresponding to a third phase), and sense points 722 and 724 corresponding to the n-th inductive component 708 (e.g., corresponding to an n-th phase). Use of the sense points may allow measurement of current with high precision. For example, coupling of the sense points to the controller 116 (not shown in FIG. 7) may allow information to be provided to the controller 116 for measuring a current. In another embodiment, as further described below, sense points (e.g., the sense points 710-724) may be integral with the conducting element (e.g., the conducting element 210) for measuring current in the conducting element.

As further shown in FIG. 7, the switching elements 114 may include transistors that provide output currents I₁-I₄ through the inductive components 702-708, respectively. For example, transistors 726 and 728 may provide the output current I₁ through the inductive component 702, transistors 730 and 732 may provide the output current I₂ through the inductive component 704, transistors 734 and 736 may provide the output current I₃ through the inductive component 706, and transistors 738 and 740 may provide the output current I₄ through the inductive component 708. The transistors may be MOSFETs or any suitable transistors as described above, and either more or fewer transistors may be included in, for example, implementations with more or fewer phases.

With continued reference to FIG. 7, the currents I₁-I₄ are merged together and a total output current I_{TOTAL} is provided to the conducting element 210 for connection to the package 204 that includes the ASIC 202. The output of the power filter 112 may also include at least one decoupling capacitor, such as a first decoupling capacitor 742 and a second decoupling capacitor 744 as shown in FIG. 7. The current return path thus remains within the printed circuit board 206.

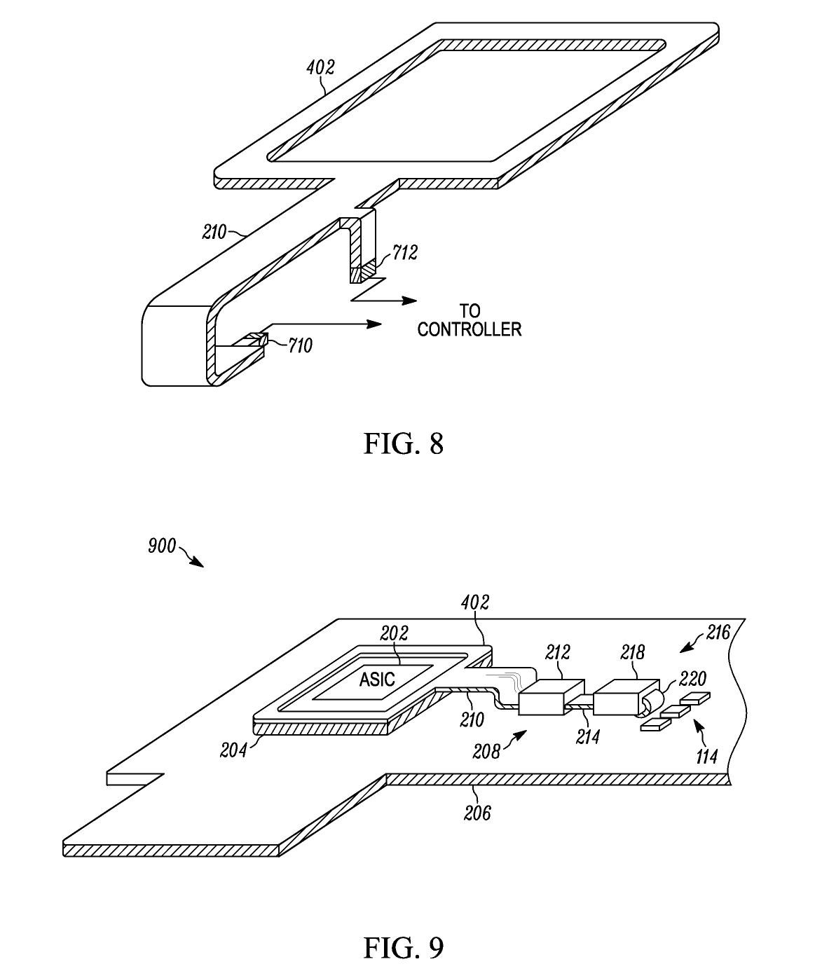

FIG. 8 illustrates an example of a conducting element having sense points integral with the conducting element. In particular, FIG. 8 illustrates an example implementation of sense points 710 and 712 corresponding to the inductive component 702 (not shown for ease of illustration), where each of sense points 710 and 712 is integral with the conducting element 210. In the particular example of FIG. 8, the conducting element 210 is also integral with the conducting element or “frame” 402 of the outer side of the package 204 as discussed above with respect to FIG. 4. As further shown in FIG. 8, each of the sense points 710 and 712 is connected to a controller (e.g., the controller 116), as discussed above, to allow information to be provided to the controller for precise current measurement at the location of the sense points. Among other advantages, such current measurement may provide an indication of whether a multi-phase integrated conducting element and magnetic cores are providing current to the package 204 that is adequate to meet the demands of the ASIC 202 or other integrated circuit or load within the package 204.

FIG. 9 illustrates yet another example electronic circuit assembly 900. The implementation in FIG. 9 is of a single-phase, multi-stage integrated conducting element and magnetic cores, as opposed to a multi-phase integrated conducting element and magnetic cores. In the example of FIG. 9, the implementation of the second integrated conducting element and inductive component 216 in a serial connection with the first integrated conducting element and inductive component 208, including the implementation of the first and second magnetic cores 212 and 218 in a serial connection, constitutes the implementation of the single-phase, multi-stage integrated conducting element and magnetic cores. As with the (first) winding element 214, the second winding element 220 may be integral with the conducting element (e.g., busbar) 210. Moreover, as mentioned previously, the first and second magnetic cores 212 and 218 may each be formed around a portion of the conducting element, e.g., busbar, 210. The magnetic cores 212 and 218 may be stamped or glued around the conducting element 210 as previously mentioned. The example of FIG. 9 also shows that the conducting element, e.g., busbar, 210 is integrated with the conducting element or frame 402 and sits on top of the package 204.

The use of a single-phase, multi-stage integrated conducting element and magnetic cores such as that shown in FIG. 9 may be advantageous in that such an implementation may effectively reduce the voltage supply noise seen by the ASIC (or other load) 202. The first magnetic core 212, which in the illustrated example represents the second stage, along with appropriate decoupling capacitors (not shown) may act as a second “noise” filter at the output of the power converter 106. It will be appreciated that while FIG. 9 shows the use of two stages, any suitable number of stages may be used. Moreover, if desired, any suitable combination of multi-stage and multi-phase implementations may be employed on the printed circuit board 206 (e.g., two phases, each with two stages, etc.) so as to further decrease power supply noise and to increase current provided to the ASIC 202 in the package 204.

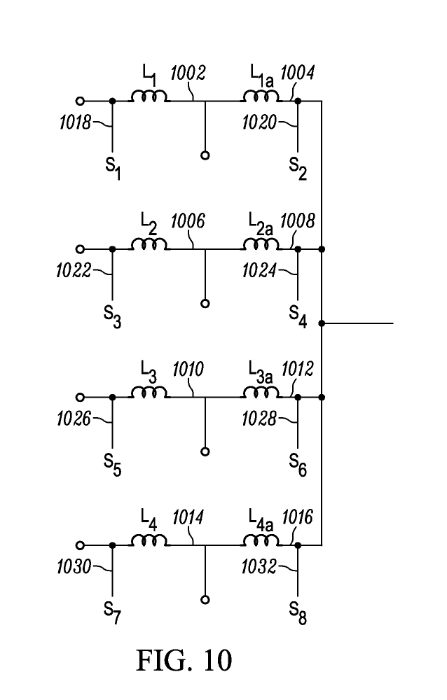

FIG. 10 is an example schematic diagram of inductive components for use in a two-stage, n-phase power converter. The schematic diagram of FIG. 10 also shows how the current can be sensed in each phase with sense point locations. Such sense points, as previously mentioned, may be part of the conducting element (e.g., busbar) 210. It will be appreciated that while two stages and n phases are illustrated in FIG. 10, any suitable number of stages may be used and any suitable number of phases including one phase may be used.

As will be understood from FIG. 10, the two-stage, n-phase integrated conducting element and magnetic cores may include inductive components 1002 and 1004 in a first phase, inductive components 1006 and 1008 in a second phase, inductive components 1010 and 1012 in a third phase, and inductive components 1014 and 1016 in an n-th phase, with further inductive components for any additional ones of the n phases not illustrated. The inductive components 1002 and 1004 may have inductances of L₁ and L₁ₐ, respectively; the inductive components 1006 and 1008 may have inductances of L₂ and L₂ₐ, respectively; the inductive components 1010 and 1012 may have inductances of L₃ and L₃ₐ, respectively; and the inductive components 1014 and 1016 may have inductances of L₄ and L₄ₐ, respectively. In one example, the inductance L₁ may be greater than the inductance L₁ₐ; the inductance L₂ may be greater than the inductance L₂ₐ; the inductance L₃ may be greater than the inductance L₃ₐ; and the inductance L₄ may be greater than the inductance L₄ₐ. The resonance formed by a second stage inductive component (e.g., L₁ₐ) is typically higher than that of a first stage inductive component (e.g., L₁), and thus the inductance of a second stage inductive component may be smaller than the inductance of the respective first stage inductive component. However, the inductances may have any suitable values and need not have the aforementioned relative magnitudes.

As further shown in FIG. 10, the two-stage, n-phase integrated conducting element and magnetic cores may include sense points 1018 and 1020 corresponding to the first phase; sense points 1022 and 1024 corresponding to the second phase; sense points 1026 and 1028 corresponding to the third phase; and sense points 1030 and 1032 corresponding to the fourth phase. The sense points 1018-1032 may be sense points such as those described above.

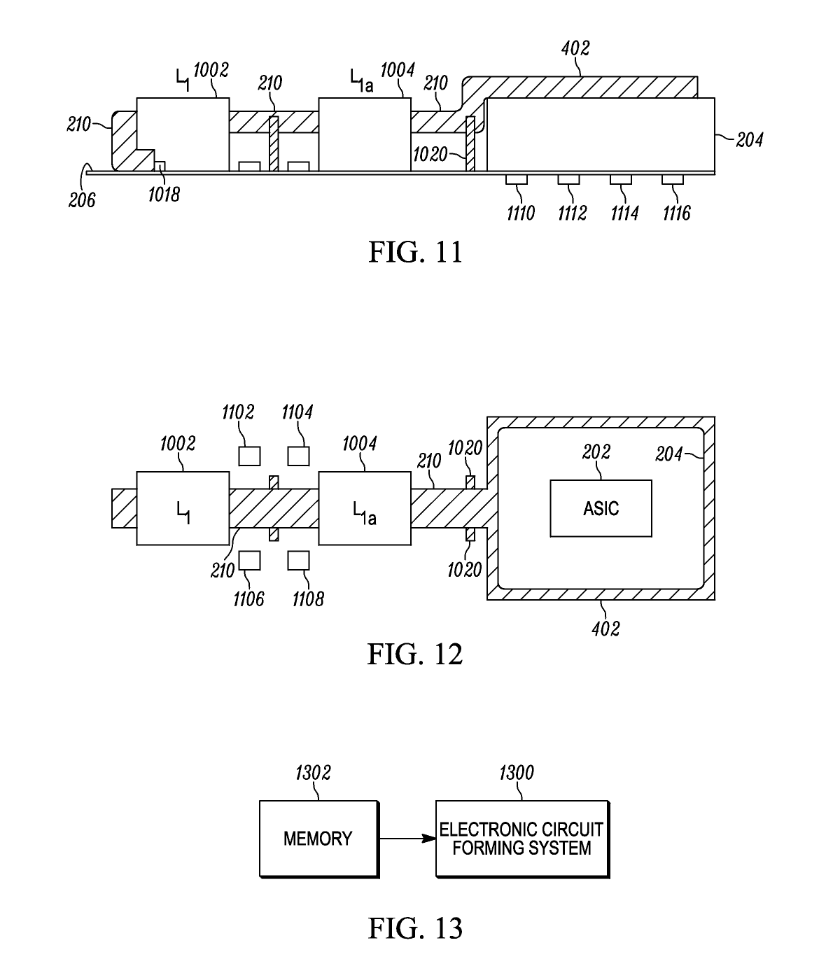

FIGS. 11 and 12 are a side view and a top view, respectively, of the integrated conducting element and magnetic cores, and the package 204 and other components described below, as mounted on the printed circuit board 206 to implement one phase of an example two-stage, n-phase power converter. As shown in FIG. 11, the conducting element 210 may be integral with the sense point 1018 corresponding to the first phase. As also shown in both FIGS. 11 and 12, one or more decoupling capacitors, such as decoupling capacitors 1102, 1104, 1106, and 1108, may be disposed on a top surface of the printed circuit board 206. In other embodiments, one or more decoupling capacitors may be disposed on a bottom side of the printed circuit board 206 instead of or in addition to being disposed on the top side of the printed circuit board 206. The conducting element 210 may also connect to the top surface of the printed circuit board 206 as shown in FIGS. 11 and 12. The conducting element 210 may further connect to the top surface of the printed circuit board 206 and to the sense point 1020, as also shown in both FIGS. 11 and 12. The conducting element 210 may also connect to the package 204 including the ASIC 202 and may, as noted above with respect to FIG. 4, be integral with the conducting element or “frame” 402 of the outer side of the package 204. One or more additional decoupling capacitors, such as decoupling capacitors 1110, 1112, 1114, and 1116, may be, for example, disposed under the package 204 that includes the ASIC 202, such as on a bottom side of the printed circuit board 206, to decouple a return path from the current path.

As shown in FIG. 13, an electronic circuit forming system 1300 may include access to memory 1302 which may be in any suitable form and any suitable location accessible via the web, accessible via hard drive or any other suitable way. The memory 1302 is a non-transitory computer readable medium such as but not limited to RAM, ROM, and any other suitable memory. The electronic circuit forming system may be one or more work stations and/or other devices that control electronic circuit formation by, for example, surface mounting, soldering, pressing, and/or any other suitable circuit formation techniques to form electronic circuits. The memory 1302 may include thereon instructions that when executed by one or more processors causes the electronic circuit forming system to form an electronic circuit that includes the structure and features described herein.

The disclosed electronic circuit designs may be employed in any suitable apparatus including but not limited to, for example, video game consoles, handheld devices such as smart phones, phablets, tablets, portable devices such as laptops, desktop computers, high definition televisions, printers or copiers, or any other suitable device. Such devices may include for example, a display that is operatively coupled to the electronic circuit where the electronic circuit may include, for example, a CPU and a GPU, such as a CPU and a GPU integrated within an APU, or any other suitable electronic circuit(s) that provides image data for output on the display. Such an apparatus may employ the electronic circuit(s) as noted above including, for example, the package comprising the integrated circuit and the integrated conducting element and inductive element disposed on a printed circuit board and connected to the package.

Also, electronic circuit forming systems may create electronic circuits based on executable instructions stored on a computer readable medium such as but not limited to CDROM, RAM, other forms of ROM, hard drives, distributed memory, etc. The instructions may be represented by any suitable language such as but not limited to hardware descriptor language (HDL), Verilog or other suitable language. As such, the electronic circuits described herein may also be produced as electronic circuits by such systems using the computer readable medium with instructions stored therein. For example, an electronic circuit with the aforedescribed features and structure may be created using such electronic circuit forming systems. In such a system, the computer readable medium stores instructions executable by one or more electronic circuit forming systems that causes the one or more electronic circuit forming systems to produce an electronic circuit. The electronic circuit includes, for example, the package comprising the integrated circuit and the integrated conducting element and inductive element disposed on a printed circuit board and connected to the package.

Among other advantages, for example, the disclosed methods and apparatus avoid the need to use power planes within a printed circuit board to deliver current to a processor, ASIC, etc. Losses may thus be minimized and printed circuit board layout and size flexibility may be increased. The need to use inner layers of the printed circuit board to connect an inductor used in the power converter to a power delivery plane may be avoided. Additionally, having the conducting element integral with the magnetic element(s) disposed on the printed circuit board, instead of within the printed circuit board, improves performance and effectiveness in power delivery and improves the ease of thermal regulation relative to known techniques. Other advantages will be recognized by one of ordinary skill in the art.

The foregoing description has been presented for the purposes of illustration and description. It is not intended to be exhaustive or to limit the invention to the exemplary embodiments disclosed. Many modifications and variations are possible in light of the above teachings. It is intended that the scope of the invention be limited not by this detailed description of examples, but rather by the claims appended hereto.

What is claimed is:

1. An apparatus comprising:
a package comprising a load; and
an integrated conducting element and inductive element disposed on a printed circuit board and connected to the package comprising the load, the integrated conducting element and inductive element comprising a conducting element integral with an inductive element, the inductive element comprising a magnetic element and a winding element, wherein the winding element comprises a portion of the conducting element.

2. The apparatus of claim 1, wherein the load comprises an integrated circuit.

3. The apparatus of claim 1, wherein the integrated conducting element and inductive element is operatively coupled to switching elements of a power converter so that the power converter is configured to control a current provided to the load by the integrated conducting element and inductive element without providing the current to the load through a plane within the printed circuit board.

4. The apparatus of claim 1, wherein the inductive element is a first inductive element, the magnetic element is a first magnetic element, and the winding element is a first winding element, wherein the integrated conducting element and inductive element comprises a second inductive element that includes a second magnetic element and a second winding element, wherein the first and second magnetic elements are each integral with the conducting element, and wherein the first and second winding elements are each comprised of a portion of the conducting element.

5. The apparatus of claim 1, wherein the integrated conducting element and inductive element is connected to the package in a first plane and mounted to the printed circuit board in a second plane, and wherein soldering compensates for misalignment between the integrated conducting element and inductive element and the package in the first plane and compensates for misalignment between the integrated conducting element and inductive element and the printed circuit board in the second plane.

6. The apparatus of claim 1, wherein the conducting element comprises a busbar.

7. The apparatus of claim 6, wherein the package comprises an outer side having a conducting element around a border of the outer side, and wherein the conducting element around the border of the outer side of the package is integral with the conducting element of the integrated conducting element and inductive element.

8. The apparatus of claim 1, wherein the inductive element is a first inductive element, wherein the integrated conducting element and inductive element comprises a second inductive element serially connected to the first inductive element, and wherein the first inductive element and the second inductive element are both integral with the conducting element.

9. The apparatus of claim 1, wherein the conducting element comprises at least one fold so as to provide increased inductance of the integrated conducting element and inductive element relative to an inductance the integrated conducting element and inductive element would have without the at least one fold.

10. The apparatus of claim 1, comprising at least one set of sense points integral with the conducting element, the at least one set of sense points operatively coupled to a controller so as to provide information to the controller for measuring a current in the conducting element.

11. The apparatus of claim 1, comprising at least one decoupling capacitor disposed under the package comprising the integrated circuit.

12. The apparatus of claim 1, wherein the load comprises an integrated circuit, and wherein the apparatus comprises:
a controller of a power converter;
switching elements of a power converter, wherein the integrated conducting element and inductive element is operatively coupled to the switching elements of the power converter so that the power converter is configured to control a current provided to the integrated circuit by the integrated conducting element and inductive element; and
one or more of an input device, an output device, and an input/output device operatively coupled to the integrated circuit.

13. A method of making an electronic circuit, comprising:
disposing a package comprising a load on a printed circuit board; and
disposing an integrated conducting element and inductive element on the printed circuit board so that the integrated conducting element and inductive element connects to the package comprising the load, the integrated conducting element and inductive element comprising a conducting element integral with an inductive element, the inductive element comprising a magnetic element and a winding element, the winding element being comprised of a portion of the conducting element.

14. The method of claim 13, wherein the load comprises an integrated circuit.

15. The method of claim 13, comprising disposing the integrated conducting element and inductive element on the printed circuit board so that the integrated conducting element and inductive element is operatively coupled to elements of a buck converter so that the buck converter is configured to control a current provided to the load by the integrated conducting element and inductive element without providing the current to the load through a plane within the printed circuit board.

16. The method of claim 13, wherein the inductive element is a first inductive element, the magnetic element is a first magnetic element, and the winding element is a first winding element, the method comprising forming the integrated conducting element and inductive element so that the integrated conducting element and inductive element comprises a second inductive element that includes a second magnetic element and a second winding element, so that the first and second magnetic elements are each integral with the conducting element, and so that the first and second winding elements are each comprised of a portion of the conducting element.

17. The method of claim 13, comprising:
connecting the integrated conducting element and inductive element to the package in a first plane; and
connecting the integrated conducting element and inductive element to the printed circuit board using at least one through hole.

18. A non-transitory computer readable medium comprising executable instructions that when executed cause an electronic circuit forming system to form an electronic circuit that comprises:
a package comprising a load; and
an integrated conducting element and inductive element disposed on a printed circuit board and connected to the package comprising the load, the integrated conducting element and inductive element comprising a conducting element integral with an inductive element, the inductive element comprising a magnetic element and a winding element, wherein the winding element comprises a portion of the conducting element.

19. The non-transitory computer readable medium of claim 18, comprising executable instructions that when executed cause the electronic circuit forming system to form the electronic circuit such that the integrated conducting element and inductive element is operatively coupled to switching elements of a power converter so that the power converter is configured to control a current provided to the load by the integrated conducting element and inductive element without providing the current through a plane within the printed circuit board.

20. The non-transitory computer readable medium of claim 18, wherein the inductive element is a first inductive element, the magnetic element is a first magnetic element, and the winding element is a first winding element, and wherein the non-transitory computer readable medium comprises executable instructions that when executed cause the electronic circuit forming system to form the electronic circuit such that the integrated conducting element and inductive element comprises a second inductive element that includes a second magnetic element and a second winding element, such that the first and second magnetic elements are each integral with the conducting element, and such that the first and second winding elements are each comprised of a portion of the conducting element.
